(19) United States
(12) Patent Application Publication
(10) Pub. No.: US 2015/0256128 A1
(43) Pub. Date: Sep. 10, 2015

(54) MULTI-PORT AMPLIFIER AND METHOD FOR CONTROLLING THEREOF

(71) Applicant: Electronics and Telecommunications Research Institute, Daejeon (KR)

(72) Inventors: Seong Mo MOON, Daejeon (KR); Dong Hwan SHIN, Daejeon (KR); Moon Que LEE, Seoul (KR); Han Lim LEE, Seoul (KR); So Hyeun YUN, Daejeon (KR); In Bok YOM, Daejeon (KR)

(73) Assignee: Electronics and Telecommunications Research Institute, Daejeon (KR)

(21) Appl. No.: 14/294,699

(22) Filed: Jun. 3, 2014

(30) Foreign Application Priority Data
Mar. 4, 2014 (KR) 10-2014-0025436

(51) Int. Cl. H03F 1/02; H04B 7/185; H03F 3/19

(52) U.S. Cl. CPC H03F 1/02; H03F 3/19; H04B 7/185; H03F 2200/451

(57) ABSTRACT

The present invention provides a multi-port amplifier which adopts a pair of SP4T switches and a pair of hybrid couplers in order to flexibly adjust an amplification mode. By using the proposed invention, the limited system flexibility and reconfigurability due to fixed input and output relations are overcome regardless of a component failure in a system. Moreover, signal amplification based on effective signal distribution and combination can be consistently performed according to various port configurations by different switching modes. Thus, the overall practicality of outputs comparing to the conventional multi-port amplifier can be effectively increased within an available lifespan of the system.

### CROSS-REFERENCE TO RELATED APPLICATIONS

This application claims priority to and the benefit of Korean Patent Application No. 10-2014-0025436 filed in the Korean Intellectual Property Office on Mar. 4, 2014, the entire contents of which are incorporated herein by reference.

### TECHNICAL FIELD

The present invention relates to a multi-port amplifier and a method for controlling the same, and particularly, to a multi-port amplifier which improves a selectivity of an output port by flexibly controlling a switching mode of a hybrid matrix and a method for controlling the same.

### BACKGROUND ART

A multi-port amplifier (MPA) is an apparatus or a device which is used for a communication satellite transponder to perform an output power controlling function. A general multi-port amplifier has a structure which applies a signal through an input port which is determined by a fixed input/output matrix and then obtains a desired signal through a determined output port so that there is a limitation in adjustment of a flexible signal flow between an input and an output. That is, the input/output port of the general multi-port amplifier is determined by an input/output matrix and the determined input and output relations are changed only by an operation of a phase shifter of a signal path. Further, in the case of four ports, only four methods are applicable to the relations.

A general multi-port amplifier is configured by connecting a plurality of hybrid couplers such as a butler matrix. Further, even though input signals are distributed or combined by distributing and combining the signals in accordance with a phase and an amplitude of a signal which passes through the coupler, the general multi-port amplifier is implemented by combining couplers, which are a passive element, so that a flow of the input/output signal is fixed. Therefore, in the multi-port amplifier system which shares a plurality of high power amplifiers (HPA) through an input/output matrix, when one high power amplifier fails or one signal path in arrays of several flows fails, the signals may not be smoothly combined or distributed so that performance of the entire system is degraded.

### SUMMARY OF THE INVENTION

The present invention has been made in an effort to provide a multi-port amplifier in which a switch such as a single-pole four throw (SP4T) is applied to a hybrid matrix to output outputs having various phases and amplitudes, which are effectively distributed and combined according to a switching mode, through an output port and a method for controlling the same.

An exemplary embodiment of the present invention provides a multi-port amplifier including multiple input terminals and multiple output terminals, including: one or more matrix cells of two inputs-two outputs type to distribute and combine signals, wherein each matrix cell comprises two switching units which operate in switching modes including an open-circuit mode, a short-circuit mode, an inductor connection mode, or a capacitor connection mode in accordance with a control signal, respectively; and two hybrid units which are combined between the two switching units and receive each of input signals and synthesize input signals to generate synthesized output signals.

The multi-port amplifier may further include amplifiers which amplify output signals of the one or more matrix cells respectively.

The multi-port amplifier may further include one or more second matrix cells which have the same configuration as the one or more matrix cells to distribute and combine outputs of the amplifiers.

Each of the one or more matrix cells and each of the one or more second matrix cells further may include a second matrix cell with the same configuration as the matrix cell, and the matrix cell and the second matrix cell may be connected in a cascaded manner.

The one or more matrix cells and the one or more second matrix cells may further include three matrix cells with the same configuration as the matrix cell to form first to fourth matrix cells, and one of two outputs of the first matrix cell and the second matrix cell may be input to the third matrix cell respectively and the other output may be input to the fourth matrix cell respectively.

The switching unit may provide an impedance of ∞ in the open-circuit mode, an impedance of zero in the short-circuit mode, an impedance of +j25Ω in the inductor connection mode, and an impedance of −j25Ω in the capacitor connection mode.

The multi-port amplifier may be applied in order to distribute and combine transmission/reception signals in a multi beam antenna system, a communication and broadcasting satellite payload system, or a satellite transponder.

The switching unit may include a single-pole four throw (SP4T) switch.

The hybrid unit may include a 3-dB coupler.

Another exemplary embodiment of the present invention provides method for controlling a multi-port amplifier including multiple input terminals and multiple output terminals, the method including: in each of one or more two inputs-two outputs matrix cells to distribute and combine signals, (A) operating, by two switching units, in switching modes including an open-circuit mode, a short-circuit mode, an inductor connection mode, and a capacitor connection mode in accordance with a control signal respectively; and (B) receiving, by two signal synthesizing units which are combined between the two switching units, each of input signals, synthesizing input signals and generating synthesized output signals.

The method may further include amplifying the output signals to generate amplified signals respectively.

The method may further include distributing and combining, by one or more second matrix cells with the same configuration as the one or more matrix cells, the amplified signals.

The one or more matrix cells and the one or more second matrix cells may distribute and combine the signals further using a second matrix cell which has the same configuration as the matrix cell which performs steps (A) and (B) and is connected in a cascaded manner.

The one or more matrix cells and the one or more second matrix cells may further include three matrix cells with the same configuration as the matrix cell, which perform steps (A) and (B), to form first to fourth matrix cells, and one of two outputs of the first matrix cell and the second matrix cell may be input to the third matrix cell respectively and the other output may be input to the fourth matrix cell respectively.

The switching unit may provide an impedance of ∞ in the open-circuit mode, an impedance of zero in the short-circuit mode, an impedance of +j25Ω in the inductor connection mode, and an impedance of −j25Ω in the capacitor connection mode.

The multi-port amplifier may be applied in order to distribute and combine transmission/reception signals in a multi beam antenna system, a communication and broadcasting satellite payload system, or a satellite transponder.

The switching unit may include a single-pole four throw (SP4T) switch.

The synthesizing unit may include a 3-dB coupler.

According to a multi-port amplifier and a method for controlling the same according to the exemplary embodiment of the present invention, a switch such as an SP4T is applied to the hybrid matrix in order to adjust an output mode setting so that a limitation in system flexibility and reconstruction due to fixed input and output relations is overcame. Further, even though failure or a problem occurs in an amplifier of the system or other circuit configurations in accordance with a usage circumstance, the amplifier or other circuit configurations may be continuously used with a port configuration by effective signal distribution and combination in accordance with a switching mode, thereby increasing an availability of an output by twice or more a conventional multi-port amplifier and prolonging an available lifespan of the system.

### BRIEF DESCRIPTION OF THE DRAWINGS

FIG. 1 is a diagram of a multi-port amplifier according to an exemplary embodiment of the present invention.

FIG. 2A is a diagram of a matrix cell of FIG. 1.

FIG. 2B is a view illustrating a switching unit of FIG. 2A.

FIG. 3 is a view illustrating an example of an output option when the matrix cells of FIG. 1 are connected in a cascaded manner.

FIG. 4 is a view illustrating an operation of hybrid matrices of FIG. 1.

FIG. 5 is a flowchart illustrating a method for controlling a multi-port amplifier according to an exemplary embodiment of the present invention.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Hereinafter, the present invention will be described in detail with reference to accompanying drawings. In this case, like components are denoted by like reference numerals in the drawings, if possible. Further, a detailed description of a function and/or a configuration which has been already publicly known will be omitted. In the following description, parts which are required to understand an operation according to various exemplary embodiments will be mainly described and a description on components which may cloud a gist of the description will be omitted.

Some components of the drawings may be exaggerated, omitted, or schematically illustrated. However, a size of the component does not completely reflect an actual size and thus the description is not limited by a relative size or interval of the components illustrated in the drawings.

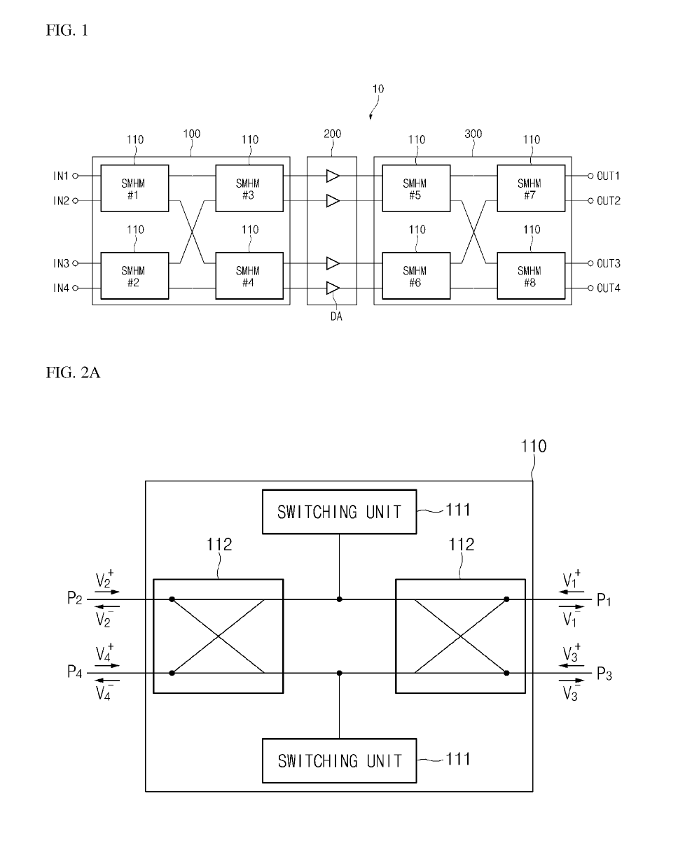

FIG. 1 is a diagram of a multi-port amplifier 10 according to an exemplary embodiment of the present invention.

As illustrated in FIG. 1, the multi-port amplifier 10 includes an input hybrid matrix 100, an amplifying unit 200, and an output hybrid matrix 300.

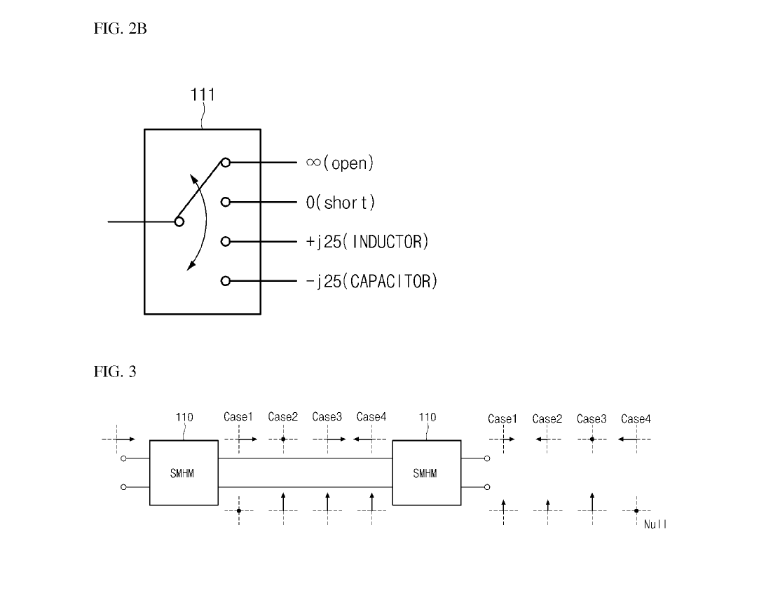

As will be described below with reference to FIG. 2, the input hybrid matrix 100 and the output hybrid matrix 300 may include four two inputs-two outputs matrix cells 110 which are unit switching mode hybrid matrix (SMHM) cells, respectively. As will be described below, each matrix cell 110 may operate in various switching modes (for example, an open-circuit mode (impedance ∞), a short-circuit mode (impedance 0), an inductor connection mode (impedance +j25Ω), and a capacitor connection mode (impedance −j25Ω)) in order to effectively distribute and combine signals, and output output signals Out1, Out2, Out3, and Out4 having various phases and amplitudes through an output terminal with respect to input signals IN1, IN2, IN3, and IN4 which are input to an input terminal by various combination thereof.

The multi-port amplifier 10 may include a plurality of input terminals and a plurality of output terminals in which the number of input terminals and output terminals is 2ⁿ (here, n is a natural number). Therefore, the multi-port amplifier 10 having 2, 4, 8, 16, . . . input/output terminals may be configured and may have various configurations depending on a design of a designer in consideration of an implementation availability or an optimal performance.

That is, for the 4×4 (four inputs-four outputs) multi-port amplifier 10, the input hybrid matrix 100 is configured by a plurality of matrix cells 110 (#1, #2, #3, and #4) and two outputs ports of the matrix cell #1 are connected to input ports of the matrix cells #3 and #4, respectively. Further, two output ports of the matrix cell #2 are connected to the input ports of the matrix cell #3 and #4, respectively. However, for the 2×2 multi-port amplifier, when the matrix cells #2 and #4 are not provided, two output ports of the matrix cell #1 may be connected to two input ports of the matrix cell #3. In accordance with a configuration of the system, the input hybrid matrix 100 may be configured by one matrix cell 110 or may include more matrix cells 110.

In FIG. 1, the hybrid matrix 100 distributes and combines input signals IN1, IN2, IN3, and IN4 in accordance with an operation corresponding to a switching mode of the plurality of matrix cells 100 (#1, #2, #3, and #4) and outputs corresponding synthesized (distributed and combined) signals to the amplifying unit 200 (see step S510 of FIG. 5).

The amplifying unit 200 amplifies the synthesized signals, which are output at a predetermined frequency band through four output ports of the input hybrid matrix 100, using drive amplifiers DAs to output corresponding amplified signals to the output hybrid matrix 300 (see step S520 of FIG. 5).

Similarly to the configuration of the input hybrid matrix 100 described above, a configuration of the output hybrid matrix 300 is configured by a plurality of matrix cells 110 #5, #6, #7, and #8 and two output ports of the matrix cell #5 are connected to input ports of matrix cells #7 and #8, respectively. Further, two output ports of the matrix cell #6 are connected to the input ports of matrix cells #7 and #8, respectively. However, for the 2×2 multi-port amplifier, when the matrix cells #6 and #8 are not provided, two output ports of the matrix cell #5 may be connected to two input ports of the matrix cell #7. Further, in accordance with a configuration of the system, the output hybrid matrix 300 may be configured by one matrix cell 110 or may include more matrix cells 110.

The output hybrid matrix 300 distributes and combines four output signals of the amplifying unit 200 in accordance with an operation corresponding to switching modes of the plurality of matrix cells 110 (#5, #6, #7, and #8) and outputs corresponding synthesized (distributed and combined) signals Out1, Out2, Out3, and Out4 having various phases and sizes through an output port (see step S530 of FIG. 5).

The multi-port amplifier 10 according to the exemplary embodiment of the present invention may be used to distribute and combine transmission/reception signals in a multi beam antenna system (not illustrated). That is, a multi beam antenna system which provides a narrow beam having a high antenna gain in a service coverage is used for a communication and broadcasting satellite payload system due to excellent effective isotropic radiated power (EIRP) and a gain-to-noise (G/T) performance.

The multi-port amplifier 10 according to the exemplary embodiment of the present invention, which may control an output power in accordance with an operational condition, may be used in a multi beam antenna system. Further, the multi beam antenna system which uses the multi-port amplifier 10 according to the exemplary embodiment of the present invention may provide several spot beams in a service area to provide a communication and broadcasting service and further flexibly provide a high power allocation in an area which requires a higher EIRP due to rainfall or sudden increase of a communication service. Further, when high power amplifiers having the highest failure rate among components for a satellite transponder are used to be connected in parallel, if the multi-port amplifier 10 according to the exemplary embodiment of the present invention is used, a less number of high power amplifier redundancies than a conventional satellite transponder may be used to configure the system.

In the antenna system to which the multi-port amplifier 10 according to the exemplary embodiment of the present invention is applied, an RF power which is allocated to one beam may form a part (1:N) of whole available RF power rather than one to one relation with one high power amplifier HPA (DA). For example, the high power drive amplifier DA of the amplifying unit 200 receives an output signal of the input hybrid matrix 100 to amplify the output signal with an appropriately distributed power and the amplified signals may be used to create a signal required to form individual beams by the output hybrid matrix 300. By doing this, as compared with a case when one high power amplifier is used for every beam to amplify a signal, according to the exemplary embodiment of the present invention, a plurality of high power drive amplifiers DA of the amplifying unit 200 effectively distributes and combines an amplifying signal so that a size of the output is flexibly adjusted and a load of the high power amplifier is reduced. Further, in some cases, a maximum output power of each of the high power drive amplifiers DAs is used to appropriately use the entire available RF power so as to be flexibly allocated to form the antenna beam.

FIG. 2A is a diagram of the matrix cell 110 of FIG. 1.

Referring to FIG. 2A, the plurality of matrix cells 110 (#1, #2, #3, and #4) of the input hybrid matrix 100 and the plurality of matrix cells 110 (#5, #6, #7, and #8) of the output hybrid matrix 300 are configured by two switching units 111 and two hybrid units (signal synthesizing unit) 112 combined between the switching units 111.

The switching unit 111 may be a single-pole four throw (SP4T) switch and as illustrated in FIG. 2B, may operate in various switching modes (for example, an open-circuit mode (impedance ∞), a short-circuit mode (impedance 0), an inductor connection mode (impedance +j25Ω), and a capacitor connection mode (impedance −j25Ω)) in accordance with a control signal of a control unit (not illustrated) to provide a load impedance in accordance with the corresponding mode.

The two hybrid units 112 may be 3-dB couplers and receive an input signal (for example, an RF signal) through input ports P1/P2 which are connected to each unit 112 in accordance with the corresponding load impedance which is provided in accordance with the switching mode of the switching unit 111, and synthesize the received signals in accordance with the combined structure to create synthesized output signals and output the output signals through the output ports P3/P4.

For example, when P1, P2, P3, and P4 are used as input ports P1 (for example, a voltage V1), an isolation port P2 (for example, a voltage V2=0), output ports P3 and P4 (for example, voltages V3 and V4) and there are no reflected signals from the input port P1 and the isolation port P2, the following Equation 1 may be obtained.

$$[ \begin{matrix}{V}_{3}^{-} \\ {V}_{4}^{-}\end{matrix} ] = [ \begin{matrix}\frac{{Z}_{o}}{2 x + {jZ}_{o}} & \frac{j 2 x}{2 x + {jZ}_{o}} \\ \frac{j 2 x}{2 x + {jZ}_{o}} & \frac{{Z}_{o}}{2 x + {jZ}_{o}}\end{matrix} ] \cdot [ \begin{matrix}{V}_{3}^{+} \\ {V}_{4}^{+}\end{matrix} ] \qquad [ Equation 1 ]$$

In Equation 1, when a signal is applied only to the input port P1 (V2+=0), Equations 2 and 3 are obtained, and finally a relation between the output signals may be represented by Equation 4.

$$\begin{matrix}{V}_{3}^{-} = \frac{j 2 x}{2 x + {jZ}_{o}} {V}_{1}^{+} & [ Equation 2 ] \\ {V}_{4}^{-} = \frac{{Z}_{o}}{2 x + {jZ}_{o}} {V}_{1}^{+} & [ Equation 3 ] \\ \frac{{V}_{3}^{-}}{{V}_{4}^{-}} = \frac{j 2 x}{{Z}_{o}} & [ Equation 4 ]\end{matrix}$$

Here, x is a corresponding load impedance according to the switching mode (for example, an open-circuit mode (impedance ∞), a short-circuit mode (impedance 0), an inductor connection mode (impedance +j25Ω), and a capacitor connection mode (impedance −j25Ω)) of the switching unit 111, and Z₀ is a characteristic impedance of corresponding transmission line.

In this case, for example, in the open-circuit mode (x=∞) of the two switching units 111, the matrix cell 110 may output the output signal only to the port P3. Further, in the short-circuit mode (x=0) of the two switching units 111, the matrix cell 110 may output the output signal only to the port P4.

In order to distribute the input signal to the ports P3 and P4 so as to have the same size, a condition of |j2×|=|Z₀| needs to be satisfied so that if ωL=Z₀/2 (in an inductor L connection mode of the two switching units 111), a phase difference between signals of the ports P3 and P4 is 90 degree, and if ωC=Z₀/2 (in a capacitor C connection mode of the two switching units 111), a phase difference between signals of the ports P3 and P4 is −90 degree.

When a signal is applied to the input ports P1 and P2, output options of output ports P3 and P4 in the matrix cell 110 in accordance with the operation of the hybrid unit 112 according to the switching modes of the switching unit 111 will be represented in the following Table 1.

TABLE 1

| Switch Mode | | | | | |
|---|---|---|---|---|---|
| (load | | Mode 1: | Mode 2: | Mode 3: | Mode 4: |
| impedance) | | (open) | (short) | (+j25Ω) | (−j25Ω) |
| Input to P₁ | Output P₃ | 1 | 0 | $\frac{- j}{\sqrt{2}}$ | $\frac{1}{\sqrt{2}}$ |
| | Output P₄ | 0 | 1 | $\frac{1}{\sqrt{2}}$ | $\frac{- j}{\sqrt{2}}$ |
| Input to P₂ | Output P₃ | 0 | 1 | $\frac{1}{\sqrt{2}}$ | $\frac{- j}{\sqrt{2}}$ |
| | Output P₄ | 1 | 0 | $\frac{- j}{\sqrt{2}}$ | $\frac{1}{\sqrt{2}}$ |

As described above, by providing the load impedance according to the switching mode (for example, an open-circuit mode (impedance ∞), a short-circuit mode (impedance 0), an inductor connection mode (impedance +j25Ω), and a capacitor connection mode (impedance −j25Ω)) of the switching unit 111, the hybrid unit 112 may output various types of input signals to the output ports P3 and P4.

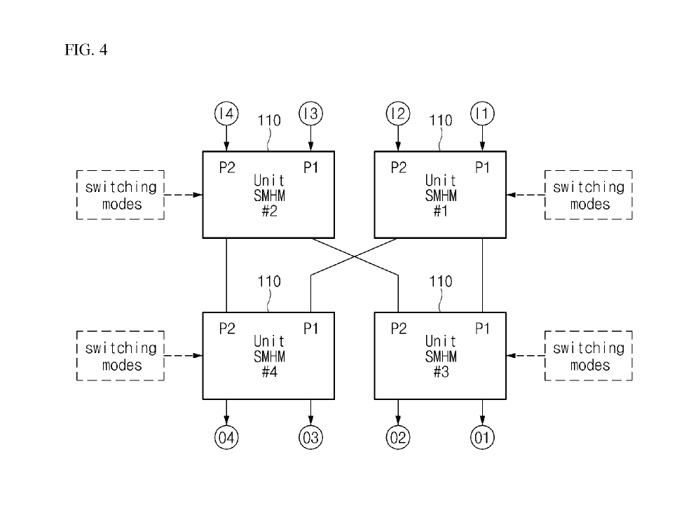

FIG. 3 is a view illustrating an example of an output option when two or more matrix cells 110 of FIG. 1 are connected in a cascaded manner.

As illustrated in FIG. 3, the matrix cell 110 may output two input signals as four distributed and combined signals according to the switching mode of the switching unit 111 as represented in Equation 4 and generate another four distributed and combined signals with the two outputs of the matrix cell 110 as two inputs of another matrix cell 110 to output various output signals having four cases of signal amplitudes and phases.

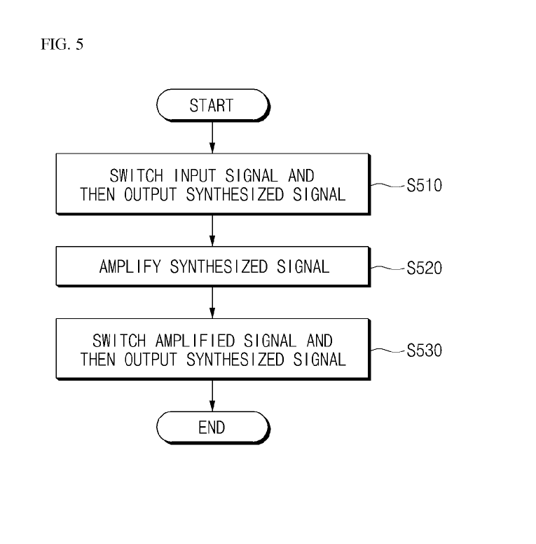

In the meantime, in FIG. 1, the input hybrid matrix 100 or the output hybrid matrix 300 may output output signals 01, 02, 03, and 04 having various phases and amplitudes through the output port by various combinations through effective distribution and combination for input signals I1, I2, I3, and I4, as illustrated in FIG. 4, in accordance with operations according to the switching modes of the matrix cells 110. The following Table 2 is a table exemplifying signals 01, 02, 03, and 04 which are output when a signal is applied to an input port 1 (11) of the matrix cell 110 (#1) in the case when the switching units 111 of the cells 110 #1 and #2 among the matrix cells 110 (#1, #2, #3, and #4) of the input hybrid matrix 100 are in the same switching mode and the switching units 111 of the cells 110 #3 and #4 are in the same switching mode.

Even though all cases for all input ports 11, 12, 13, and 14 are not exemplified in Table 2, the same result as Table 2 may be output for corresponding inputs of the input ports due to a circuit symmetry in each cell 110.

TABLE 2

| | | | | |
|---|---|---|---|---|
| SMHM | #4 Mode1: | #4 Mode2: | #4 Mode3: | #4 Mode4: |
| # | (open) | (short) | (+j25 Ω) | (−j25 Ω) |
| #3 Mode1: | o₁ = 1 | o₂ = 1 | o₂ = −j/\sqrt{2}, | o₂ = 1/\sqrt{2}, |
| (open) | | | o₁ = 1/\sqrt{2} | o₁ = −j/\sqrt{2} |
| #3 Mode2: | o₃ = 1 | o₄ = 1 | o₄ = −j/\sqrt{2}, | o₄ = 1/\sqrt{2}, |
| (short) | | | o₃ = 1/\sqrt{2} | o₃ = −j/\sqrt{2} |
| #3 Mode3: | o₃ = −j/\sqrt{2}, | o₄ = −j/\sqrt{2}, | o₄ = −1/2, o₃ = −j/2 | o₄ = −j/\sqrt{2}, o₃ = −1/2 |
| (+j25 Ω) | o₁ = 1/\sqrt{2} | o₂ = 1/\sqrt{2} | o₂ = −j/2, o₁ = 1/2 | o_{₂} = 1/2, o₁ −j/2 |
| #3 Mode4: | o₃ = 1/\sqrt{2}, | o₄ = 1/\sqrt{2}, | o₄ = −j/2, o₃ = 1/2 | o₄ = 1/2, o₃ = −j/2 |
| (−j25 Ω) | o₁ = −j/\sqrt{2} | o₂ = −j/\sqrt{2} | o₂ = −1/2, o₁ = −j/2 | o₂ = −j/2, o₃= −1/2 |
| SMHM | #2 Mode1: | #2 Mode2: | #2 Mode3: | #2 Mode4: |
| # | (open) | (short) | (+j25 Ω) | (−j25 Ω) |

When an input signal is applied to the IN4 input terminal, among the multi input terminals of the 4×4 multi-port amplifier 10 illustrated in FIG. 1, as represented in the following Table 3, signals which are distributed and combined to be amplified are output to one output terminal (single Out1), two output terminals (dual Out1 and Out2) or four output terminals (quad Out1, Out2, Out3, and Out4) using all of the matrix cells 110 (#1, #2, #3, and #4) of the input hybrid matrix 100, the matrix cells 110 (#5, #6, #7, and #8) of the output hybrid matrix 300, and four drive amplifiers DAs of the amplifying unit 200. A reference single Ref. single of Table 3 is an example when one drive amplifier is used to transmit a signal to one output terminal Out1 and is an example when only one genuine drive amplifier including an insertion loss of the input hybrid matrices 100 and 200 is used.

TABLE 3

| | Switched-impedance corresponding to unit-SMHM | | | | | | | | Used |
|---|---|---|---|---|---|---|---|---|---|
| | #1 | #2 | #3 | #4 | #5 | #6 | #7 | #8 | DA #'s |
| Single: | +j25 Ω | +j25 Ω | +j25 Ω | +j25 Ω | +j25 Ω | +j25 Ω | +j25 Ω | +j25 Ω | 1, 2, |
| Out 1 | | | | | | | | | 3, 4 |
| Dual: | +j25 Ω | +j25 Ω | +j25 Ω | +j25 Ω | +j25 Ω | +j25 Ω | open | open | 1, 2, |
| Out 1, 2 | | | | | | | | | 3, 4 |
| Quad: Out | +j25 Ω | +j25 Ω | +j25 Ω | +j25 Ω | open | open | open | open | 1, 2, |
| 1, 2, 3, 4 | | | | | | | | | 3, 4 |
| Ref. | open | open | open | open | short | short | short | short | 1 |
| Single: Out1 | | | | | | | | | |

As described above, in the multi-port amplifier 10 according to the exemplary embodiment of the present invention, in order to adjust the output mode setting, the multi-port amplifier 10 including a matrix cell 110, which operates in various switching modes by an SP4T switch, is provided so that limitation in system flexibility and reconstruction due to fixed input and output relations is overcame. Further, even though failure or a problem occurs in an amplifier of the system or other circuit configurations in accordance with a usage circumstance, the amplifier or other circuit configurations may be continuously used with a port configuration by effective distribution and combination according to a switching mode, thereby increasing an availability of an output by twice or more a conventional multi-port amplifier and prolonging an available lifespan of the system.

The present invention has been described with reference to specified matters and limited exemplary embodiments and drawings such as specific elements for general understanding of the present invention, but the present invention is not limited to the exemplary embodiments, and various modifications and changes are possible by those skilled in the art without departing from an essential characteristic of the present invention. Therefore, the spirit of the present invention is defined by the appended claims rather than by the description preceding them, and all changes and modifications that fall within metes and bounds of the claims, or equivalents of such metes and bounds are therefore intended to be embraced by the range of the spirit of the present invention.

What is claimed is:

1. A multi-port amplifier including multiple input terminals and multiple output terminals, comprising:
one or more matrix cells of two inputs-two outputs type to distribute and combine signals,
wherein each matrix cell comprises two switching units which operate in switching modes including an open-circuit mode, a short-circuit mode, an inductor connection mode, or a capacitor connection mode in accordance with a control signal, respectively; and two hybrid units which are combined between the two switching units and receive each of input signals and synthesize input signals to generate synthesized output signals.

2. The multi-port amplifier of claim 1, further comprising:
amplifiers which amplify output signals of the one or more matrix cells respectively.

3. The multi-port amplifier of claim 2, further comprising:
one or more second matrix cells which have the same configuration as the one or more matrix cells to distribute and combine outputs of the amplifiers.

4. The multi-port amplifier of claim 1, wherein each of the one or more matrix cells further include a second matrix cell with the same configuration as the matrix cell, and the matrix cell and the second matrix cell are connected in a cascaded manner.

5. The multi-port amplifier of claim 1, wherein the one or more matrix cells further include three matrix cells with the same configuration as the matrix cell to form first to fourth matrix cells, and one of two outputs of the first matrix cell and the second matrix cell is input to the third matrix cell respectively and the other output is input to the fourth matrix cell respectively.

6. The multi-port amplifier of claim 1, wherein the switching unit provides an impedance of ∞ in the open-circuit mode, an impedance of zero in the short-circuit mode, an impedance of +j25Ω in the inductor connection mode, and an impedance of −j25Ω in the capacitor connection mode.

7. The multi-port amplifier of claim 1, wherein the multi-port amplifier is applied in order to distribute and combine transmission/reception signals in a multi beam antenna system, a communication and broadcasting satellite payload system, or a satellite transponder.

8. The multi-port amplifier of claim 1, wherein the switching unit includes a single-pole four throw (SP4T) switch.

9. The multi-port amplifier of claim 1, wherein the hybrid unit includes a 3-dB coupler.

10. A method for controlling a multi-port amplifier including multiple input terminals and multiple output terminals, the method comprising:
in each of one or more two inputs-two outputs matrix cells to distribute and combine signals,
(A) operating, by two switching units, in switching modes including an open-circuit mode, a short-circuit mode, an inductor connection mode, and a capacitor connection mode in accordance with a control signal respectively; and
(B) receiving, by two signal synthesizing units which are combined between the two switching units, each of input signals, synthesizing input signals and generating synthesized output signals.

11. The method of claim 10, further comprising:
amplifying the output signals to generate amplified signals respectively.

12. The method of claim 11, further comprising:
distributing and combining, by one or more second matrix cells with the same configuration as the one or more matrix cells, the amplified signals.

13. The method of claim 10, wherein the one or more matrix cells distribute and combine the signals further using a second matrix cell which has the same configuration as the matrix cell which performs steps (A) and (B) and is connected in a cascaded manner.

14. The method of claim 10, wherein the one or more matrix cells further include three matrix cells with the same configuration as the matrix cell, which perform steps (A) and (B), to form first to fourth matrix cells, and one of two outputs of the first matrix cell and the second matrix cell is input to the third matrix cell respectively and the other output is input to the fourth matrix cell respectively.

15. The method of claim 10, wherein the switching unit provides an impedance of ∞ in the open-circuit mode, an impedance of zero in the short-circuit mode, an impedance of +j25Ω in the inductor connection mode, and an impedance of −j25Ω in the capacitor connection mode.

16. The method of claim 10, wherein the multi-port amplifier is applied in order to distribute and combine transmission/reception signals in a multi beam antenna system, a communication and broadcasting satellite payload system, or a satellite transponder.

17. The method of claim 10, wherein the switching unit includes a single-pole four throw (SP4T) switch.

18. The method of claim 10, wherein the signal synthesizing unit includes a 3-dB coupler.
